(19) United States
(12) Patent Application Publication
(10) Pub. No.: US 2024/0063605 A1
(43) Pub. Date: Feb. 22, 2024

(54) OPTICAL DEVICE, METHOD OF FORMING THE SAME, AND METHOD OF CONTROLLING THE SAME

(71) Applicant: Nanyang Technological University, Singapore (SG)

(72) Inventors: Donguk NAM, Singapore (SG); Youngmin KIM, Singapore (SG); Yongduck JUNG, Singapore (SG); Daniel BURT, Singapore (SG); Hyo Jun JOO, Singapore (SG)

(21) Appl. No.: 18/268,026

(22) PCT Filed: Dec. 28, 2021
(86) PCT No.: PCT/SG2021/050826

§ 371 Date: Jun. 16, 2023

(30) Foreign Application Priority Data
Jan. 15, 2021 (SG) 10202100459Y

(51) Int. Cl. H01S 5/10; H01S 5/125; H01S 5/32; H01S 5/026

(52) U.S. Cl. CPC H01S 5/1017; H01S 5/125; H01S 5/3201; H01S 5/3223; H01S 5/0261; H01S 5/0014

(57) ABSTRACT

According to embodiments of the present invention, an optical device is provided. The optical device includes a substrate, a semiconductor layer on the substrate, the semiconductor layer having an initial tensile strain and including a monolithic crossbeam structure defined therein, and an optical cavity optically coupled to the monolithic crossbeam structure, wherein the monolithic crossbeam structure has a first beam and a second beam arranged at least substantially orthogonal to each other and intersecting each other at an intersection region, the intersection region being subjected to a tensile strain that is increased relative to the initial tensile strain. According to further embodiments of the present invention, a method of forming an optical device and a method of controlling an optical device are also provided.

### CROSS-REFERENCE TO RELATED APPLICATION

This application claims the benefit of priority of Singapore patent application No. 10202100459Y, filed 15 Jan. 2021, the content of it being hereby incorporated by reference in its entirety for all purposes.

### TECHNICAL FIELD

Various embodiments relate to an optical device, a method of forming an optical device, and a method of controlling an optical device.

### BACKGROUND

During the last few years, there have been relentless efforts to transform germanium (Ge) into a direct bandgap material for high-performance on-chip laser applications, and ultimately for the realisation of photonic-integrated circuits. The leading forms of band engineering for achieving on-chip lasing from Ge include uniaxial and biaxial strain engineering, both of which lower the direct conduction Γ valley faster than the indirect L valleys. Among a large variety of strain engineering platforms (including the use of external stressor layers), the geometrical strain amplification technique has been widely used particularly for uniaxial strain engineering. The formation of a substantially large uniaxial strain of up to a few percent enabled by the geometrical amplification technique has led to the successful development of Ge lasers. Notably, a direct bandgap has been achieved by inducing a 5.9% uniaxial strain. Such a large uniaxial strain narrows the bandgap severely and shifts the emission wavelength beyond >3.5 μm. Despite new possibilities towards free-space mid-infrared sensing applications, the mid-infrared emission renders it impossible for the uniaxially strained Ge lasers to be employed for optical communication applications (including optical board-to-board communication applications) owing to the opaque nature of silica-based optical fibers.

Biaxial strain has a unique advantage in that the bandgap narrowing by biaxial strain is substantially smaller compared to the uniaxial case. In fact, the direct bandgap that can be achieved by >1.67% biaxial strain allows the emission wavelength to be located ˜2 μm, thus enabling biaxially strained Ge lasers to be employed for fiber-based optical communications. Recently, by using the external stressor layer technique, biaxially strained Ge microdisk lasers in a direct bandgap configuration have been demonstrated with the emission wavelength of ˜2 μm. However, the use of an external stressor layer requires precise control of the stressor layer thickness, which otherwise could lead to a significant gain broadening owing to strain inhomogeneity within the active gain medium. In addition, the strain level is purely determined by the thickness and the residual stress of the stressor layer, both of which are predetermined at the stage of the wafer bonding. Lithographically tunable biaxial strain enabled by the geometrical strain amplification technique has been reported. Although this technique poses distinctive advantages towards creating biaxially strained Ge lasers in terms of strain homogeneity and tunability, the understanding of the optical gain in such structures remains missing.

Some technologies used in the field of strained Ge lasers include geometrically amplified uniaxial strain structures, which demonstrate the possibility of amplifying strain using geometrical amplification technique. However, such structures were only optimized for uniaxial strain. The main disadvantage of these technologies is that the uniaxial strain shifts the laser emission too far to the mid-infrared, rendering the uniaxially strained Ge lasers not suitable for fiber-based optical communications.

Other technologies used in the field of strained Ge lasers include biaxial strain structures with external stressor, which demonstrate the ability to induce biaxial strain using external stressor layers such as stressed silicon nitride. However, the induced strain in the gain medium is determined by the thickness of the stressor layer, which prevents one from tuning the strain via lithography. Also, the strain distribution is highly non-uniform because stressor induces the strain to be more localised towards the interface between the stressor layer and the active layer to be strained. The main disadvantage of these technologies can be summarised as incapability to tune the strain, and strain inhomogeneity.

Further technologies used in the field of strained Ge lasers include geometrically amplified biaxial strain structures, which provide structures that can enable the creation of biaxial strain using geometrical amplification technique. However, there is a lack of understanding of optical gain in these structures.

### SUMMARY

The invention is defined in the independent claims. Further embodiments of the invention are defined in the dependent claims.

According to an embodiment, an optical device is provided. The optical device may include a substrate, a semiconductor layer on the substrate, the semiconductor layer having an initial tensile strain and including a monolithic crossbeam structure defined therein, and an optical cavity optically coupled to the monolithic crossbeam structure, wherein the monolithic crossbeam structure has a first beam and a second beam arranged at least substantially orthogonal to each other and intersecting each other at an intersection region, the intersection region being subjected to a tensile strain that is increased relative to the initial tensile strain.

According to an embodiment, a method of forming an optical device is provided. The method may include forming a semiconductor layer on a substrate, the semiconductor layer that is formed having an initial tensile strain, forming a monolithic crossbeam structure in the semiconductor layer, wherein the monolithic crossbeam structure includes a first beam and a second beam arranged at least substantially orthogonal to each other and intersecting each other at an intersection region, the intersection region being subjected to a tensile strain that is increased relative to the initial tensile strain, and optically coupling an optical cavity to the monolithic crossbeam structure.

According to an embodiment, a method of controlling an optical device is provided. The method may include applying an input light to an intersection region of the optical device described herein.

### BRIEF DESCRIPTION OF THE DRAWINGS

In the drawings, like reference characters generally refer to like parts throughout the different views. The drawings are not necessarily to scale, emphasis instead generally being placed upon illustrating the principles of the invention. In the following description, various embodiments of the invention are described with reference to the following drawings, in which:

FIG. 1A shows a simplistic top view of an optical device, according to various embodiments.

FIG. 1B shows a flow chart illustrating a method of forming an optical device, according to various embodiments.

FIG. 1C shows a method of controlling an optical device, according to various embodiments.

FIGS. 2A to 2C show a schematic illustration of the fabrication process for an optical device, according to various embodiments.

FIGS. 2D and 2E show scanning electron microscopy (SEM) images of an optical device, according to various embodiments. Scale bars represent 20 μm.

FIGS. 3A and 3B show respectively a top view and a cross-sectional view of simulated electric field distributions in a crossbeam structure that achieves a high-quality factor of >4,000. Scale bars represent 10 μm.

FIG. 4A shows the simulated biaxial strain distribution in the crossbeam structure of various embodiments. Scale bar represents 10 μm.

FIG. 4B shows the measured biaxial strain distribution via Raman mapping in the crossbeam structure of various embodiments. Scale bar represents 1 μm.

FIG. 4C shows a plot of lateral strain variation over a 10-μm length around the center of the gain medium.

FIG. 5A shows results of photoluminescence (PL) from crossbeam structures with different applied biaxial strains, while FIG. 5B shows results for the linewidth of the cavity modes and the integrated PL intensity as a function of biaxial strain.

FIG. 6A shows results for the pump-power dependence of photoluminescence (PL) spectra of a 0.86%-strained structure measured at 4 K, while FIG. 6B shows results of the linewidth of the cavity mode at ˜1,940 nm and the integrated PL intensity as a function of pump power.

FIG. 7A shows results of the temperature dependence of photoluminescence (PL) spectra of a 0.86%-strained structure measured between about 4 K and about 300 K, while FIG. 7B shows results of the linewidth of the cavity mode at ˜1,940 nm as a function of temperature.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Embodiments described in the context of one of the methods or devices are analogously valid for the other methods or devices. Similarly, embodiments described in the context of a method are analogously valid for a device, and vice versa.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the phrase “at least substantially” may include “exactly” and a reasonable variance.

In the context of various embodiments, the term “about” or “approximately” as applied to a numeric value encompasses the exact value and a reasonable variance.

As used herein, the term “and/or” includes any and all combinations of one or more of the associated listed items.

The creation of CMOS (complementary metal-oxide-semiconductor) compatible light sources is an important step for the realisation of electronic-photonic integrated circuits. The integration of photonic devices into CMOS electronic circuits is an enabler for the realisation of electronic-photonic integrated circuits. An efficient CMOS-compatible light source is considered the final missing component towards achieving this goal. The techniques disclosed herein may provide a crossbeam structure with an embedded optical cavity that allows both a relatively high and fairly uniform biaxial strain of ˜0.9% in addition to a high-quality factor of >4,000 simultaneously. The induced biaxial strain in the crossbeam structure may be conveniently tuned by varying one or more geometrical factors that may be defined by lithography. Comprehensive photoluminescence measurements and analyses, as will be discussed further below, confirm that optical gain may be significantly improved via the combined effect of low temperature and high strain, which is supported by a three-fold reduction of the full width at half maximum of a cavity resonance at ˜1,940 nm. The demonstration opens up the possibility of further improving the performance of germanium (Ge) lasers by harnessing geometrically amplified biaxial strain.

Structures having a biaxial strain, particularly when they are to be combined with an optical cavity, are challenging to achieve. Cavity integration is challenging because it requires a careful optimisation of the mirror designs and locations to avoid or minimise any disruption of the homogeneous strain profile in the gain medium. While known approaches may provide geometrically amplified biaxial strain structures, the integration of optical cavity, which is required towards the realisation of biaxially strained Ge lasers, is entirely missing. Therefore, although the lithographically tunable biaxial strain enabled by the geometrical strain amplification technique poses distinctive advantages towards creating biaxially strained Ge lasers in terms of strain homogeneity and tunability, the understanding of the optical gain in such structures remains missing largely owing to the challenges in embedding high-quality optical cavities without or minimally disturbing the homogeneous strain distribution.

Various embodiments may provide a biaxially strained crossbeam germanium (laser) structure. As a non-limiting example, various embodiments may provide a biaxially strained germanium crossbeam with a high-quality optical cavity for on-chip light or laser applications.

Various embodiments may provide a crossbeam structure that may achieve a lithographically tunable biaxial strain with embedded distributed Bragg reflector (DBR) mirrors. By employing the geometrical strain amplification technique along two orthogonal axes, a fairly or highly uniform strain distribution may be obtained within the gain medium. The DBR mirrors are carefully designed to have a high-quality factor of >4,000 without or minimally disturbing the strain homogeneity, allowing for the demonstration of a high-quality factor optical cavity for geometrically enhanced biaxial strain. Quality factor may be defined as the ratio of stored energy in the optical cavity to the energy dissipated per cycle. The higher the quality factor, the longer the light confined within the optical cavity may survive.

Finite-element method (FEM) mechanical simulations along with 2D Raman mapping, as will be described further below, provide results for the uniformity of the induced biaxial strain. A comprehensive photoluminescence (PL) study has been carried out to investigate the effect of strain, temperature, and pump power on the optical gain in biaxially strained Ge. In various embodiments, the biaxial strain may be further enhanced by lowering the sample temperature because of the thermal expansion coefficient mismatch between silicon (Si) and Ge. This may be due to the increased residual strain in the Ge layer that is induced by the thermal expansion coefficient mismatch. The combined effect of temperature and strain is found to have a profound impact on the optical gain, which is evidenced by a three-fold reduction of the full width at half maximum (FWHM) of a cavity resonance at ˜1,940 nm. The techniques disclosed herein pave the way towards creating biaxially strained Ge lasers for fiber-based optical communication applications.

The (monolithic) crossbeam structure of various embodiments may simultaneously induce a highly uniform biaxial strain (˜1%) and achieve high-quality factor (>4,000). The induced biaxial strain in the crossbeam structure may be conveniently tuned by varying one or more geometrical factors that may be defined by lithography without or minimally being affected by the presence of (four) highly sophisticated DBR mirrors. Such geometrical factors may include the width and/or length (i.e., size) of the stressing pads or elements defining the crossbeam structure. The amount of biaxial strain may be tuned by varying the size or dimension(s) of the stressing elements.

The techniques disclosed herein may provide one or more of the following features: (1) capability to create uniform and large biaxial strain in Ge, (2) ability to integrate DBR mirrors (for example, for all 4 sides of the crossbeam structure), (3) geometrical variable strain without requiring external stressors.

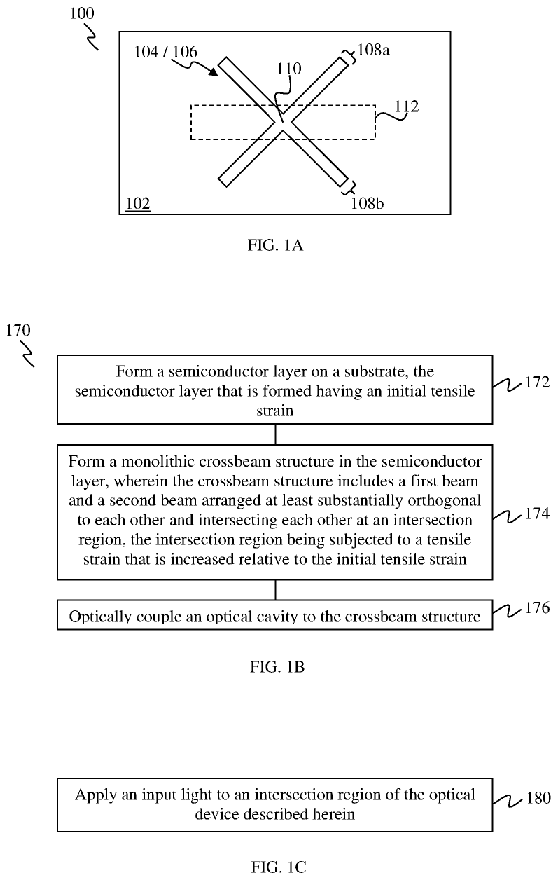

FIG. 1A shows a simplistic top view of an optical device 100, according to various embodiments. The optical device 100 includes a substrate 102, a semiconductor layer 104 on the substrate 102, the semiconductor layer 104 having an initial tensile strain and including a monolithic crossbeam structure 106 defined therein, and an optical cavity (defined by the dashed box 112) optically coupled to the monolithic crossbeam structure 106, wherein the monolithic crossbeam structure 106 includes a first beam and a second beam 108a, 108b arranged at least substantially orthogonal to each other and intersecting each other at an intersection region 110, the intersection region 110 being subjected to a tensile strain that is increased relative to the initial tensile strain.

In other words, an optical device 100 is provided, having a substrate or substrate arrangement 102, and a semiconductor layer 104 formed on or over the substrate 102. The semiconductor layer 104, as formed on the substrate 102, has an initial (or original) tensile strain. The formed semiconductor layer 104 includes a monolithic crossbeam structure 106 defined therein. The monolithic crossbeam structure 106 includes a first beam (e.g., 108a) and a second beam (e.g., 108b) arranged at least substantially orthogonal to each other. This means that the first beam 108a and the second beam 108b are arranged at least substantially perpendicular to each other. The first beam 108a and the second beam 108b intersect or overlap each other at an intersection region 110. The intersection region 110 of the monolithic crossbeam structure 106 formed on the substrate 102 is subjected to a tensile strain that is higher relative to the initial tensile strain. The optical device 100 further includes an optical cavity 112 optically coupled to the monolithic crossbeam structure 106.

The semiconductor layer 104 has an initial tensile strain induced therein as a result of being formed on the substrate 102, for example, as a result of a mismatch between characteristics or parameters associated with the substrate 102 and the semiconductor layer 104, e.g., a difference in their respective thermal expansion coefficients. The initial tensile strain may include or may be the residual strain in the semiconductor layer 104 after being formed on the substrate 102.

The monolithic crossbeam structure 106 may be formed in the semiconductor layer 104. The semiconductor layer 104 may be patterned, for example via lithography, and etched, to define the monolithic crossbeam structure 106.

The crossbeam structure 106, being a monolithic structure, means that the crossbeam structure 106 is a single continuous structure. The first beam 108a and the second beam 108b are made of or include the same semiconductor material. The monolithic crossbeam structure 106 may allow optical fields to overlap with the intersection region 110. By providing a monolithic crossbeam structure 106, only one step of lithography is required to define the monolithic crossbeam structure 106 for the strain amplification technique, without having any external stressors that are incorporated in known approaches. This is helpful, for example, from the point of view of commercial applications because yields deteriorate, and process costs increase, for fabrication with additional fabrication processes.

The intersection region 110 means the region where the first beam 108a and the second beam 108b overlap each other.

The intersection region 110 may be located at the center of the monolithic crossbeam structure 106.

The intersection region 110 is a strained region. A uniform strain distribution may be provided or generated at the intersection region 110.

Due to the nature of the monolithic crossbeam structure 106, the intersection region 110 is subjected to an increased tensile strain.

The intersection region 110 is subjected to an increased tensile strain that is generated biaxially in directions along (the longitudinal axes of) the first beam 108a and the second beam 108b. Due to the nature of the monolithic crossbeam structure 106, biaxial tensile strain acts on the intersection region 110 of the monolithic crossbeam structure 106 where the biaxial tensile strain is along the two orthogonal axes corresponding to the first and second beams 108a, 108b. The amount or magnitude of the biaxial tensile strain is higher compared to the initial tensile strain of the semiconductor layer 104. The biaxial strain may be uniformly distributed over the intersection region 110.

In various embodiments, the amount of the (increased) tensile strain that the intersection region 110 may be subjected to may be between about 0.2% and about 1.7%, or even more. As non-limiting examples, the tensile strain may be between about 0.2% and about 2.0%, between about 0.2% and about 1.5%, between about 0.2% and about 1.0%, between about 1.0% and about 2.0%, or between about 1.5% and about 2.0%.

In various embodiments, light may propagate through the monolithic crossbeam structure 106 or the optical device 100. Light may propagate in a direction at least substantially parallel to the semiconductor layer 104, for example, at least substantially parallel to a major surface of the semiconductor layer 104.

The optical cavity 112 may be defined in or using the semiconductor layer 104.

The optical cavity 112 may provide light confinement. The optical cavity 112 may confine light within the monolithic crossbeam structure 106 or the optical device 100. For example, the optical cavity 112 may confine light propagating through or along the first beam 108a and/or the second beam 108b. The light confined by the optical cavity 112 may propagate back and forth, through the intersection region 110, along the first beam 108a and/or the second beam 108b. Therefore, the propagating light or the associated optical field (or optical mode) may overlap with the intersection region 110.

The intersection region 110, and, therefore, the monolithic crossbeam structure 106, is in an optical path of the light propagating within the optical cavity 112.

In various embodiments, the intersection region 110 may define an active region or a gain medium. A gain medium is the source of optical gain that allows to amplify light and make stronger light by means of stimulated emission. The intersection region 110, being strained, may provide or enhance optical gain of the optical device 100. As such, light propagating through the intersection region 110 may experience gain or may be amplified.

In various embodiments, the monolithic crossbeam structure 106 may be suspended over the substrate 102. This means that the monolithic crossbeam structure 106 may be spaced from the substrate 102 by an air gap therebetween. The suspended nature of the monolithic crossbeam structure 106 may allow for a higher increase, relative to the initial tensile strain, in the tensile strain acting (biaxially) on the intersection region 110.

In various embodiments, a plurality of etched regions may be defined in the semiconductor layer 104 to define the monolithic crossbeam structure 106, the plurality of etched regions being arranged along two orthogonal axes. The plurality of etched regions may be openings or holes etched (entirely) through the semiconductor layer 104. A respective etched region of the plurality of etched regions may be arranged between the first beam 108a and the second beam 108b.

The two orthogonal axes corresponding to the plurality of etched regions may be shifted relative to the longitudinal or orthogonal axes corresponding to the first and second beams 108a, 108b, for example, shifted by 45°.

For each etched region of the plurality of etched regions, the etched region is defined by a first section (e.g., a head section) having a curvature that tapers decreasingly in a direction towards the intersection region 110, and a second section (e.g., a tail section) extending from the first section in a direction away from the intersection region 110. Therefore, each first section may have a curved boundary. Each first section may taper to a narrow(er) end region pointing to the intersection region 110 or the center of the intersection region 110. Each second section may be at least substantially straight. The width of each second section may be at least substantially uniform. Each second section may be narrower than the associated first section. Each second section may be longer than the associated first section.

The first sections of adjacent etched regions of the plurality of etched regions may define a neck region therebetween, wherein a minimum width of the neck region may be between about 700 nm and about 2000 nm (i.e., 2 μm). As non-limiting examples, the minimum width may be between about 700 nm and about 1500 nm, between about 700 nm and about 1000 nm, between about 1000 nm and about 2000 nm, or between about 1500 nm and about 2000 nm, e.g., about 1000 nm (i.e., 1 μm). If the minimum width of the neck region is too small, the size of the intersection region 110 may be too small to amplify light. If the minimum width of the neck is too large, it becomes more challenging to obtain a large amount of strain because the area under the tensile strain increases.

In various embodiments, the optical cavity may be defined by a (first) pair of distributed Bragg reflectors (DBRs) arranged on opposite sides of the intersection region 110 along a longitudinal axis of the first beam 108a. Each DBR may be or may act as a mirror. The pair of DBRs may serve to reflect light effectively towards the intersection region 110 to confine the light. The pair of DBRs may serve to confine light along the (longitudinal) axis of the first beam 108a. A respective DBR of the pair of DBRs may be arranged between two adjacent etched regions. Each DBR (or the parameter(s) thereof) may be designed to correspond to the wavelength of the light to be confined.

The pair of DBRs may be embedded in the semiconductor layer 104. The semiconductor layer 104 may be patterned to define the pair of DBRs.

Each DBR of the pair of DBRs may have a curvature that is curved away from the intersection region 110. The curvature may be designed to match the distribution of the light, which diverges in a direction away from the intersection region 110 as it propagates, at the DBR to minimise optical loss. The curvature may be between about 15 μm and about 20 μm, for example, between about 15 μm and about 18 μm, or between about 18 μm and about 20 μm.

In various embodiments, a distance between each DBR and the intersection region 110 may be between about 12 μm and about 20 μm, for example, between about 12 μm and about 15 μm, or between about 15 μm and about 20 μm, e.g., about 13.5 μm.

For each DBR of the pair of DBRs, a plurality of air trenches may be defined in the DBR, wherein a number of the plurality of air trenches may be between 7 and 10, e.g., 7. Accordingly, each DBR may include a sequence of air and the material of the semiconductor layer 104 arranged alternately. In other words, each DBR may have a structure having alternating air trenches and semiconductor layer material. Air and the material of the semiconductor layer 104 have different refractive indices such that light may be reflected at the interface thereof due to such difference.

If the number of air trenches is too small, e.g., less than 7, less light may be reflected, and, thus, light may not be confined effectively. If most of the light is already reflected from or by the front portion of each DBR, the air trenches at the back portion of the DBR may not help or contribute to the performance of the DBR. As a non-limiting example, 7 air trenches may be sufficient to confine the light effectively.

In various embodiments, a width of each air trench of the plurality of air trenches may be between about 275 nm and about 442 nm, for example, between about 275 nm and about 400 nm, between about 275 nm and about 350 nm, between about 350 nm and about 442 nm, or between about 350 nm and about 400 nm.

In various embodiments, a period of the plurality of air trenches may be between about 295 nm and about 462 nm. In other words, the distance between two adjacent air trenches may be about 295-462 nm. As non-limiting examples, the period may be between about 295 nm and about 420 nm, between about 295 nm and about 350 nm, between about 350 nm and about 462 nm, or between about 350 nm and about 420 nm.

The air trench width and/or period may be designed to provide sufficient light confinement. The air trench width and/or period may be designed to correspond to the wavelength of the light to be confined.

The optical cavity may be further defined by an additional (or second) pair of distributed Bragg reflectors (DBRs) arranged on opposite sides of the intersection region 110 along a longitudinal axis of the second beam 108b. The additional pair of DBRs may serve to reflect light effectively towards the intersection region 110 to confine the light. The additional pair of DBRs may serve to confine light along the (longitudinal) axis of the second beam 108b. It should be appreciated that description in the context of the pair of DBRs arranged along the first beam 108a may also be applicable to the additional pair of DBRs arranged along the second beam 108b.

The monolithic crossbeam structure 106 may further include a first pair of stressing pads (or stressing elements) extended from the first beam 108a and arranged on opposite sides of the intersection region 110 along a longitudinal axis of the first beam 108a, and a second pair of stressing pads (or stressing elements) extended from the second beam 108b and arranged on opposite sides of the intersection region 110 along a longitudinal axis of the second beam 108b. The first pair of stressing pads may be part of the first beam 108a. The second pair of stressing pads may be part of the second beam 108b.

For each stressing pad of the first pair of stressing pads and the second pair of stressing pads, the stressing pad may taper increasingly in a direction away from the intersection region 110.

The first pair of stressing pads and the second pair of stressing pads may help or act to enhance the tensile strain acting on the intersection region 110 relative to the initial tensile strain. For example, during and/or after fabrication, the first and second pairs of stressing pads may shrink or reduce in dimension or size, which induces a pulling effect on the intersection region 110, thereby increasing the tensile strain acting on the intersection region 110. The amount of the tensile stress may be tuned by varying the dimension of each stressing pad.

In various embodiments, a respective DBR of the (first) pair of DBRs may be arranged or positioned on or at a respective stressing pad of the first pair of stressing pads, while a respective DBR of the additional pair of DBRs may be arranged or positioned on or at a respective stressing pad of the second pair of stressing pads.

In various embodiments, a diameter of the intersection region 110 may be between about 1.5 μm and about 4 μm, for example, between about 1.5 μm and about 3 μm, between about 1.5 μm and about 2 μm, between about 2 μm and about 4 μm, between about 3 μm and about 4 μm, or between about 2 μm and about 3 μm, e.g., 2.42 μm.

The curvature of the intersection region 110 where the neck regions meet may be optimised by considering the optical loss and strain distribution, and the diameter of the intersection region 110 may then be determined according to the optimisation result. A reduced or lower diameter of the intersection region 110 may help to improve strain homogeneity at the intersection region 110.

In various embodiments, the semiconductor layer 104 may include a germanium-based material. As a non-limiting example, the semiconductor layer 104 may include (elemental) germanium (Ge) or may be a (elemental) Ge layer. As a further non-limiting example, the semiconductor layer 104 may include GeSn (germanium-tin) as a GeSn layer can have or be under an initial tensile strain.

In various embodiments, the thickness of the semiconductor layer (e.g., Ge layer) 104 may be between about 200 nm and about 500 nm. This may help to provide sufficient optical confinement and/or large strain. As non-limiting examples, the thickness may be between about 200 nm and about 400 nm, between about 200 nm and about 300 nm, between about 300 nm and about 500 nm, between about 400 nm and about 500 nm, or between about 300 nm and about 400 nm.

The semiconductor layer 104 may be doped. As a non-limiting example, germanium, as the semiconductor layer 104, may be doped with phosphorus (P).

In various embodiments, the substrate 102 may include or may be a silicon (Si) substrate or a silicon-on-insulator (SOI) substrate.

In various embodiments, the optical device 100 may be free of any external or additional stressor(s) (or stressor layer(s)). This means that stressor(s) (or structure(s) used to enhance strain) that are external to the monolithic crossbeam structure 106 are not provided in the optical device 100, as compared to known approaches which employ such external stressor(s) to enhance tensile strain.

In various embodiments, the optical device 100 may include or may be an optical (light) source. Output light may be provided by the optical device 100 as a result of spontaneous emission from the intersection region 110.

In various embodiments, the optical source may include or may be a laser. Output light may be provided by the optical device 100 as a result of stimulated emission from the intersection region 110.

Output light provided by the optical device 100 may propagate in a direction at least substantially parallel to the semiconductor layer 104, for example, at least substantially parallel to a major surface of the semiconductor layer 104.

The wavelength of the output light provided by the optical device 100 may be dependent on the amount of the increased tensile strain on the intersection region 110. The wavelength increases as the tensile strain increases.

In various embodiments, the optical cavity 112 may be configured or designed to allow at least a portion of the confined light or light propagating through the monolithic crossbeam structure 106 to propagate out of or be outputted from the optical cavity 112. For example, a DBR may be designed to have one or more parts through the DBR that are free of air trenches such that light may propagate through the DBR via such air trench-free part(s) of the DBR.

In various embodiments, the optical device 100 may include a photodetector as the Ge-based material may absorb light. As the increased tensile strain becomes higher, the available detection range may move towards longer wavelengths, thus, such a structure can be used as a tunable photodetector. For the photodetector, the optical cavity 112 may optionally not be required.

FIG. 1B shows a flow chart 170 illustrating a method of forming an optical device, according to various embodiments.

At 172, a semiconductor layer is formed on a substrate, the semiconductor layer that is formed having an initial tensile strain.

At 174, a monolithic crossbeam structure is formed in the semiconductor layer, wherein the monolithic crossbeam structure includes a first beam and a second beam arranged at least substantially orthogonal to each other and intersecting each other at an intersection region, the intersection region being subjected to a tensile strain that is increased relative to the initial tensile strain.

At 176, an optical cavity is optically coupled to the monolithic crossbeam structure.

At 174, the semiconductor layer may be subjected to a lithography process and an etching process to form the monolithic crossbeam structure.

In various embodiments, part of the substrate may be removed for the monolithic crossbeam structure to be suspended over the substrate.

In various embodiments, at 174, a plurality of etched regions may be defined in the semiconductor layer to form the monolithic crossbeam structure, the plurality of etched regions being arranged along two orthogonal axes. Defining the plurality of etched regions may include defining, for each etched region of the plurality of etched regions, a first section having a curvature that tapers decreasingly in a direction towards the intersection region, and a second section extending from the first section in a direction away from the intersection region.

The first sections of adjacent etched regions of the plurality of etched regions may define a neck region therebetween, wherein a minimum width of the neck region may be between about 700 nm and about 2000 nm.

In various embodiments, at 176, a pair of distributed Bragg reflectors (DBRs) arranged on opposite sides of the intersection region along a longitudinal axis of the first beam may be formed to define the optical cavity.

For each DBR of the pair of DBRs, a plurality of air trenches may be defined in the DBR, wherein a number of the plurality of air trenches may be between 7 and 10.

A width of each air trench of the plurality of air trenches may be between about 275 nm and about 442 nm.

A period of the plurality of air trenches may be between about 295 nm and about 462 nm.

A distance between each DBR of the pair of distributed Bragg reflectors and the intersection region may be between about 12 μm and about 20 nm.

In various embodiments, at 176, an additional pair of DBRs arranged on opposite sides of the intersection region along a longitudinal axis of the second beam may be formed to define the optical cavity.

In various embodiments, at 174, a first pair of stressing pads may be formed extending from the first beam and arranged on opposite sides of the intersection region along a longitudinal axis of the first beam, and a second pair of stressing pads may be formed extending from the second beam and arranged on opposite sides of the intersection region along a longitudinal axis of the second beam.

For each stressing pad of the first pair of stressing pads and the second pair of stressing pads, the stressing pad may taper increasingly in a direction away from the intersection region.

In various embodiments, a diameter of the intersection region may be between about 1.5 μm and about 4 μm.

In various embodiments, the semiconductor layer may include a germanium-based material.

FIG. 1C shows a method 180 of controlling an optical device, according to various embodiments. The method 180 includes applying an input light to an intersection region (e.g., 110, FIG. 1A) of the optical device (e.g., 100, FIG. 1A) described herein.

In various embodiments, the monolithic crossbeam structure (e.g., 106, FIG. 1A) of the optical device may be suspended over the substrate (e.g., 102, FIG. 1A) of the optical device, and the method 180 may further include decreasing a (operation) temperature of the optical device. Lowering the temperature may cause additional shrinkage of the semiconductor layer (e.g., 104, FIG. 1A) of the optical device, which may further enhance the tensile strain at the intersection region.

It should be appreciated that descriptions in the context of the optical device 100 (FIG. 1A) may correspondingly be applicable in relation to the method of forming an optical device described in the context of the flow chart 170, and the method 180 of controlling an optical device.

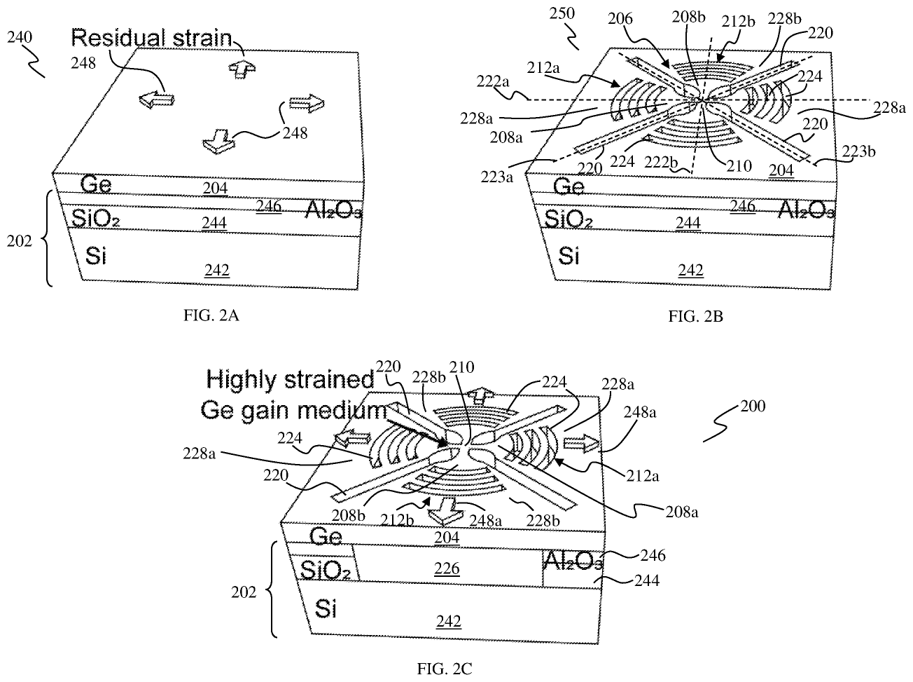

Various embodiments will now be further described by way of the following non-limiting examples with reference to FIGS. 2A to 7B. Like features or components of the optical devices shown in FIGS. 2A to 4B are denoted by the same reference numerals.

FIGS. 2A to 2C show a schematic illustration of the fabrication process for an optical device 200, according to various embodiments, showing the various processing stages of an example crossbeam structure fabrication process.

The optical device 200 may be formed using a Ge-on-insulator (GOI) substrate, which may be created by using epitaxial growth and direct wafer bonding technique. An epitaxially grown germanium (Ge) layer on a silicon (Si) carrier wafer having a 20-nm thick aluminum oxide (Al₂O₃) layer on top may be bonded to a handle Si wafer having approximately 1-μm thick thermally grown silicon dioxide (SiO₂) layer. Direct bonding may be utilised by bringing the Ge on the Si carrier wafer surface and the handle Si wafer surface into contact at room temperature. Post-bonding annealing may then be carried out at about 300° C. for about 3 hours to get a stronger bonding strength. By using wafer backgrinding and tetramethylammonium hydroxide (TMAH)-based wet etching, the Si carrier wafer may be removed, allowing the formation of a GOI wafer having the handle Si wafer. During the epitaxial growth of Ge, phosphorus (P) doping (˜6×10¹⁸ cm⁻³) may be introduced to the Ge layer.

As shown in FIG. 2A, a structure 240 may be obtained, having a substrate 202 and a Ge layer 204 on the substrate 202. The substrate 202 includes the handle Si wafer with a Si layer 242 and a SiO₂ layer 244. The substrate 202 further includes an Al₂O₃ layer 246 formed on the Si carrier wafer that has been removed. There is residual strain, as represented by the arrows 248, on the Ge layer 204 that is formed on the substrate 202. The residual strain 248 is in directions from an inner part of the Ge layer 204 towards the outer part of the Ge layer 204. Accordingly, the Ge layer 204 has an initial tensile strain. A desired Ge thickness of 300 nm may be achieved by a chemical mechanical polishing (CMP) step, which may enable a smooth surface with a surface roughness of <0.3 nm. An optimised thickness of the Ge layer may range from about 200 nm to about 500 nm to have a decent or sufficient optical confinement and large strain simultaneously. The threading dislocation density of the as-grown Ge on Si may be around 1×10⁷ cm⁻², and after the bonding procedure and removal of the defect rich Ge/Si interface, it may be around 5×10⁶ cm⁻².

Electron-beam (E-beam) fabrication may then be carried out. A monolithic crossbeam structure may be defined by electron-beam lithography (EBL) using, for example, a positive tone resist. As a non-limiting example, the positive tone resist ZEP 520A may be used. The pattern may subsequently be transferred using Cl₂⁻ (chlorine) and BCl₃-based (boron trichloride) inductively coupled plasma (ICP) dry etching.

As shown in FIG. 2B, a structure 250 may be obtained. The structure 250 includes a monolithic crossbeam structure 206 formed in the Ge layer 204. The monolithic crossbeam structure 206 includes a first beam (or arm) 208a and a second beam (or arm) 208b arranged at least substantially orthogonal to each other. The first beam 208a or its corresponding longitudinal axis may be along or parallel to a first axis represented by dashed line 222a. The second beam 208b or its corresponding longitudinal axis may be along or parallel to a second axis represented by dashed line 222b. The two axes 222a, 222b are orthogonal axes. The first beam 208a and the second beam 208b intersect or overlap each other at an intersection region 210. The intersection region 210 may be at the center or central portion of the monolithic crossbeam structure 206.

A plurality of etched regions 220, for example, four etched regions, may be patterned and etched through the Ge layer 204 to define the monolithic crossbeam structure 206. The plurality of etched regions 220 are openings or holes etched (entirely) through the Ge layer 204. The plurality of etched regions 220 are arranged along or parallel to orthogonal axes represented by dashed lines 223a, 223b. The axes 223a, 223b are shifted relative to the two axes 222a, 222b.

The structure 250 may further include a plurality of stressing pads (or stressing elements) 228a, 228b. A first pair of stressing pads 228a may be arranged extending from or as part of the first beam 208a, on opposite sides of the intersection region 210 along the axis 222a. The first pair of stressing pads 228a may be at opposite end regions of the first beam 208a. A second pair of stressing pads 228b may be arranged extending from or as part of the second beam 208b, on opposite sides of the intersection region 210 along the axis 222b. The second pair of stressing pads 228b may be at opposite end regions of the second beam 208b. The plurality of stressing pads 228a, 228b are arranged along two orthogonal axes 222a, 222b to achieve uniform biaxial strain distribution.

The structure 250 may further include an optical cavity optically coupled to the monolithic crossbeam structure 206. The Ge layer 204 may be patterned and etched to form a plurality of distributed Bragg reflectors (DBRs) 212a, 212b, for example, four DBRs, to define the optical cavity. The DRBs 212a, 212b serve to confine light within the optical cavity. A first pair of DBRs 212a may be arranged along the first beam 208a on opposite sides of the intersection region 210. Therefore, the first pair of DBRs 212a may be aligned with or coincide with the first axis 222a. A second pair of DBRs 212b may be arranged along the second beam 208b on opposite sides of the intersection region 210. Therefore, the second pair of DBRs 212b may be aligned with or coincide with the second axis 222b. A plurality of air trenches 224 may be etched into the Ge layer 204 to define each of the DBRs 212a, 212b.

The first pair of DBRs 212a may be formed or defined on the first pair of stressing pads 228a, while the second pair of DBRs 212b may be formed or defined on the second pair of stressing pads 228b. In other words, each stressing pad 228a, 228b may include a respective DBR 212a, 212b.

Isotropic wet etching in hydrofluoric (HF) acid may then be performed on the structure 250 to undercut the underlying Al₂O₃ layer 246 and SiO₂ layer 244, thus releasing the crossbeam structure 206. In this way, the monolithic crossbeam structure 206 is suspended from the substrate 202 with an air gap 226 therebetween. Finally, critical point drying (CPD) may be performed to allow for the entire structure 206 to remain suspended by preventing it from adhering to the underlying Si substrate 202. As shown in FIG. 2C, an optical device 200 may be obtained. The monolithic crossbeam structure 206 may be a central structure of the optical device 200. The DBRs or DBR mirrors 212a, 212b may be integrated at all four sides of the central structure or the crossbeam structure 206. The optical device 200 is designed for the two axes 222a, 222b to be orthogonal to each other to minimise or avoid shear stress, which may cause undesired or unwanted deformation of the intersection region 210. Such unwanted deformation may cause incomplete biaxial deformation and may cause structural fragility. Upon releasing the patterned crossbeam structure 206 in the HF-based wet etching, the residual biaxial strain in the (entire) Ge layer 204 redistributes and amplifies the (initial) strain at the center of the crossbeam structure 206, i.e., at the intersection region 210. The intersection region 210 may function as a highly strained Ge gain medium. As shown in FIG. 2C, the amplified tensile strain, as represented by the arrows 248a, acts on the intersection region 210 in directions outwardly from the intersection region 210. The increased tensile strain 248a may be in directions along the first beam 208a and the second beam 208b. In other words, the biaxial strain 248a may be generated along the longitudinal axes of the first and second beams 208a, 208b. Finite-element method (FEM) mechanical simulations have been performed, which confirms that the strain distribution is in good agreement with 2D Raman mapping results, as will be described further below.

FIGS. 2D and 2E show SEM images of an optical device 200, illustrating, respective a top view and a tilted view of a fabricated biaxially strained Ge crossbeam structure 206. A clear shadow under the central region of the crossbeam structure 206 may be observed due to the suspended nature of the crossbeam structure 206, which may help in amplifying biaxial strain at low temperatures, and, thereby enhancing optical gain. This feature will be discussed further below.

As may be more clearly observed in FIGS. 2D and 2E, each etched region 220 includes a first section 230a having a curvature or curved boundary that tapers decreasingly in a direction towards the intersection region 210, and a second section 230b extending from the first section 230a in a direction away from the intersection region 210. Each first section 230a has a bulbous-like shape that tapers to a narrow(er) end region or tip region directed to or at the intersection region 210. Each second section 230b may be narrower and longer than the corresponding first section 230a. Each second section 230b may be straight. The intersection region 210 may be bounded by the tapered end regions of the first sections 230a of the etched regions 220. The first sections 230a of adjacent etched regions 220 may define a neck region 232 therebetween, with the neck region 232 having a minimum width, t.

The stressing pads 228a, 228b may be connected to respective neck regions 232. For reference and guidance purposes, the areas corresponding to the stressing pads 228a, 228b may be enclosed, but not limited to, within the quadrilateral-shaped dashed lines 229a, 229b. It should be appreciated that the boundaries of the stressing pads 228a, 228b may not be restricted to the dashed lines 229a, 229b. As a non-limiting example, the areas adjacent to or up to the neck regions 232 may be considered part of the stressing pads 228a, 228b.

Each of the stressing pads 228a, 228b may taper increasingly in a direction away from the intersection region 210. It is preferable that the narrow(er) end regions of the stressing pads 228a, 228b point towards the center of the intersection region 210 because it is preferable that the curvature or shape of the taper that connects the intersection region 210 and the stressing pads 228a, 228b (e.g., the curvature of the connecting neck regions 232) be gentle to minimise or prevent undesired strain on the taper.

In further detail, initially, tensile strain 248 is introduced in the Ge layer 204 after the bonding processes including post-annealing and cooling down because Ge has a larger thermal expansion coefficient than that of Si. Then, HF etching may be performed to undercut the underlying Al₂O₃ layer 246 and SiO₂ layer 244, releasing and shrinking the (entire) crossbeam structure 206. When the structure 206 shrinks, the stressing pads 228a, 228b at the four sides shrink and pull the central intersection region 210 and the neck regions 232 in four directions because the size of each stressing pad 228a, 228b is larger than that of the intersection region 210 and the neck regions 232, resulting in biaxial strain 248a in the intersection region 210. The amount and/or distribution of the biaxial strain 248a may be tuned. The amount of biaxial strain 248a may be tuned by changing the size of the stressing pads 228a, 228b. The larger the stressing pads 228a, 228b are, the stronger the biaxial strain 248a that can be induced. The distribution of the biaxial strain 248a in the neck regions 232 may be tuned, depending on the curvature of the region connecting the intersection region 210 and the neck regions 232, which may be defined by the curvature of the first sections 230a of the etched regions 220.

In various embodiments, the stressing pads 228a, 228b may follow an isosceles triangular shape, which allows to achieve larger stressing pads 228a, 228b as well as more space between the edges of the DBRs 212a, 212b and the side of the stressing pads 228a, 228b. Firstly, a larger stressing pad 228a, 228b may be achieved while maintaining its length, thus, a higher strain with the same device size may be achieved. Secondly, sufficient space between the edge of a DBR 212a, 212b and the side of a stressing pad 228a, 228b can minimise or prevent a large amount of stress from forming on the edge of the DBR 212a, 212b.

The dimension of each stressing pad 228a, 228b may be determined by considering the desired or target biaxial strain. For a biaxial strain of approximately 0.86%, the length of the stressing pads 228a, 228b may be ˜80 μm, and the width of the stressing pads 228a, 228b may be ˜30 μm near the DBRs 212a, 212b and ˜160 μm at the broader end portions.

The position and/or size of the DBR mirrors 212a, 212b may depend on the distribution of the light at the DBRs 212a, 212b because light diverges as it travels through the narrow neck regions 232 towards the DBRs 212a, 212b. As a non-limiting example, the distance between each DBR 212a, 212b and the center or the intersection region may be ˜13.5 μm.

The DBR mirrors 212a, 212b are carefully designed to have a high-quality factor of >4,000. The DBRs 212a, 212b may include or consist of a sequence of Ge and air stacks which have different refractive indexes. Further, the DBRs 212a, 212b are designed such that the sum of the thicknesses of a single Ge and a single air trench 224, as a stack, correspond to the effective wavelength for the light that is to be confined. When the light travels, it is reflected at the interface between Ge and air due to the difference in the refractive index. Thus, the DBR mirrors 212a, 212b may achieve such high-quality factor by effectively confining the light within the optical cavity. The DBRs 212a, 212b may be formed by patterning the continuous air trenches 224 with a specific period.

The air trench width and period of the DBR mirrors 212a, 212b may depend on the target wavelength of the light to be confined. The curvature of the DBRs 212a, 212b may be designed to match the distribution of the diverged light at the DBRs 212a, 212b to minimise optical loss. It is preferable that the shape (curvature) of each DBR 212a, 212b matches the distribution of the diverged light.

While at least four DBRs 212a, 212b are required to confine light in directions along the two axes 222a, 222b, two DBR mirrors 212a (or 212b) are sufficient if light is to be confined in one direction, for example, along the axis 222a (or 222b).

It should be appreciated that other types of reflectors or mirrors may be employed. As a non-limiting example, corner cube shaped mirrors may be used to form or define an optical cavity.

It should be appreciated that a semiconductor layer of another material may be used in place of the Ge layer 204. The material should be CMOS-compatible and have an initial tensile strain. As a non-limiting example, any group IV materials including GeSn and SiGeSn may also be a suitable material for the semiconductor layer, instead of elemental Ge layer 204, given that the semiconductor layer can be under an initial tensile strain.

It should be appreciated that optical devices may be fabricated where the monolithic crossbeam structure 206 is not in a suspended state but in a stuck nature. For example, after etching to undercut the Al₂O₃ layer 246 and the SiO₂ layer 244, the crossbeam structure 206 may drop through the air gap 226 to contact the Si layer 242 or be stuck (or adhere to) to the Si layer 242. If desired, critical point drying (CPD) may be performed, after etching to undercut the Al₂O₃ layer 246 and the SiO₂ layer 244, to allow the monolithic crossbeam structure 206 to be in a suspended state over the Si layer 242. Nevertheless, regardless of the crossbeam structure 206 being in a suspended or stuck nature, biaxial strain 248a is induced. A suspended crossbeam structure 206 is helpful to enhance the biaxial strain 248a at lower temperatures because the Ge layer 204 is able to shrink more. If the crossbeam structure 206 is stuck on the underlying layer, it cannot be stretched more at the lower temperatures.

In various embodiments, a uniform and large biaxial strain may be generated or achieved in the Ge layer 204 by carefully optimising the crossbeam structure design. The uniform strain distribution at the intersection region 210 may be achieved by optimising the curvature of the region connecting the intersection region 210 and the neck region 232. A larger biaxial strain in Ge may be achieved by a uniform strain distribution at the intersection region 210 and lowering undesired stress at the mirror corner. Undesired corner stress may be lowered by optimising the reflector or mirror design and location.

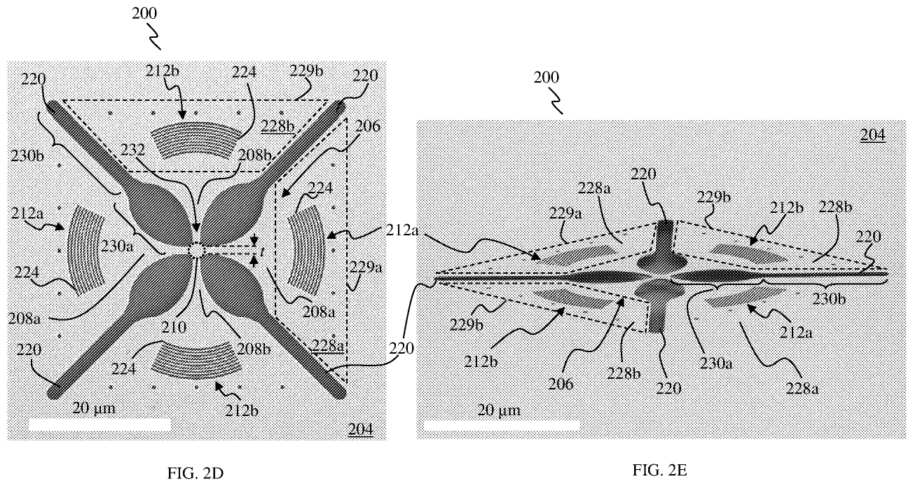

FIGS. 3A and 3B show respectively the simulated electric field distributions for the top and cross-sectional views of the biaxially strained Ge crossbeam structure 206 of various embodiments, obtained using 3D finite-domain time-difference (FDTD) simulations. In FIGS. 3A and 3B, the intensity of the electric field increases from each DBR mirror 212a, 212b in the direction (represented by the dashed arrows) towards the strained gain medium at the center (see dotted circle representing the intersection region 210 in FIG. 2D) of the crossbeam structure 206. Each DBR mirror 212a, 212b may include or may consist of 10 air trenches with width and period of about 285 nm and about 452 nm, respectively. In various embodiments, the number of (air) trenches may be as small as 7. A smaller number of trenches may induce leakage of the optical field, while a larger number of trenches may make the structure unnecessarily big. The air trench width and period are optimised by using FDTD simulations, and the trench width may range from about 275 nm to about 442 nm, while the trench period may range from about 295 nm to about 462 nm, to have good optical confinement. The curvature of circular arcs of the DBR mirrors 212a, 212b is carefully designed to achieve a high optical quality factor of >4,000. In various embodiments, the bending radius of the curvature may range from about 15 μm to about 20 μm. The crossbeam structure 206 is designed to allow optical fields to overlap with the highly strained gain medium at the center 210 of the crossbeam structure 206. The nature of the shape of the entire monolithic crossbeam structure 206 facilitates such overlapping. The light confined by the DBRs 212a, 212b continues to travel between two DBR mirrors 212a, 212b and may form a strong optical field at the intersection region 210. Thus, it is possible for the light to overlap with the intersection region (e.g., highly strained gain medium) 210 by designing the strained region at the intersection region 210. The intersection region 210, where Ge is strained, is designed to overlap with the optical mode, and which is where the optical mode is the strongest. The strained Ge, at the intersection region 210, provides the gain medium itself.

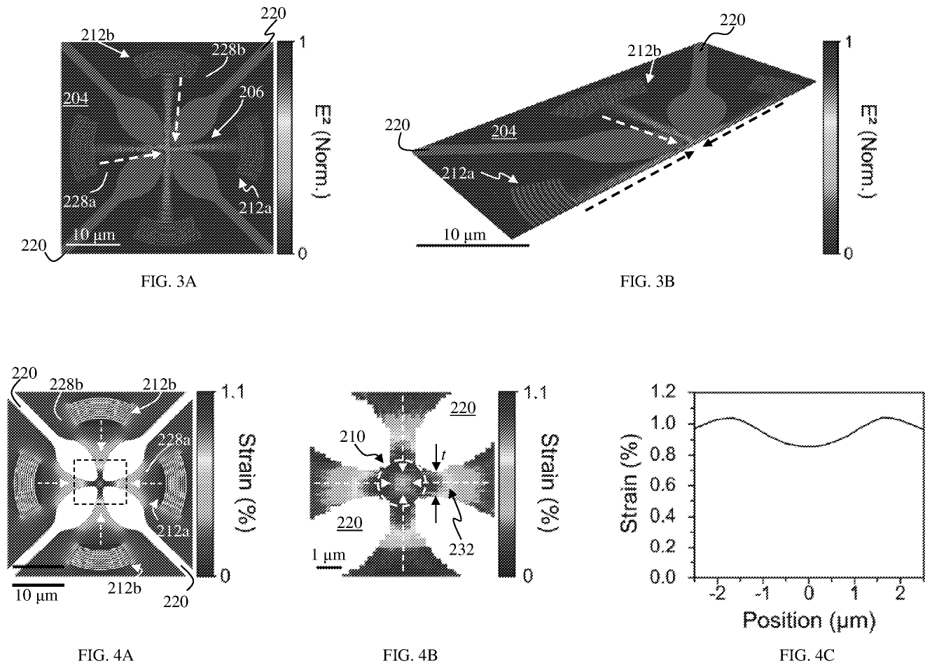

Structural analysis has been carried out. To investigate the strain distribution in the crossbeam structure, the FEM simulations have been employed using COMSOL Multiphysics. FIGS. 4A and 4B show the simulated and measured biaxial tensile strain distribution in a crossbeam structure, respectively, showing excellent agreement between the two results. In FIGS. 4A and 4B, the amount of strain increases from each DBR mirror 212a, 212b in the direction (represented by the dashed arrows) towards the strained gain medium at the center of the crossbeam structure, which is the intersection region 210. FIG. 4B shows a partial view of the crossbeam structure in the vicinity of the central gain medium 210. The portion of the crossbeam structure shown in FIG. 4B may be similar to the region enclosed within the dashed square in FIG. 4A. As may be more clearly seen in FIG. 4B, there is a neck area 232, with a minimum width, t, between the intersection region 210 and each stressing pad 228a, 228b of various embodiments. The diameter of the central area or intersection region 210 is about 2.42 μm, and the minimum width, t, of the neck regions 232 is about 1 μm, applicable for the crossbeam structures illustrated in FIGS. 4A and 4B.

The minimum width, t, of the neck regions 232 may be designed to confine the light effectively at the intersection region 210. The curvature of the region where the four neck regions 232 meet, i.e., the intersection region 210, may be optimised by considering the optical loss and strain distribution, and the diameter of the intersection region 210 may be determined according to the result. Suitable range for the diameter is about 1.5˜4 μm. If the minimum width, t, of the neck regions 232 is too small, the size of the gain medium or intersection region 210 may be too small to amplify the light. If the minimum width, t, of the neck regions 232 is too large, it may become challenging to obtain a large amount of strain because the area under the tensile stress increases. Suitable range for the minimum width, t, is 700 nm˜2 μm.

For obtaining the results of the measured biaxial strain shown in FIG. 4B, 2D Raman mapping was conducted using a 532-nm laser with low power to avoid any heating effects. By using the approach of a strain-shift coefficient for biaxial strain, a relatively homogeneous biaxial strain with a maximum value of ˜0.86% is obtained. The lateral strain variation over a 10-μm length around the center of the gain medium 210 is only ˜20%, as may be observed from the results shown in FIG. 4C, verifying a fairly or largely uniform strain distribution in the gain medium 210 that may be needed towards achieving a homogeneous optical gain. The strain homogeneity may be further improved by reducing the diameter of the central gain medium (or central area) 210. The biaxial strain may, additionally or alternatively, be increased by improving the strain homogeneity and/or by reducing the defect density during the material growth and/or bonding processes.

Cavity integration into a biaxial strain structure without or minimally disturbing the strain distribution requires careful optimisation of the mirror (DBR) designs and/or locations. Without optimisation, the uniformity of the strain profile in the gain medium and/or the quality factor of the optical cavity may be degraded or adversely affected. In various embodiments, to integrate the cavity into the biaxial strain structure, a prototype structure was first designed by simply crossing two neck regions. For the prototype, the central area or the intersection region was square rather than circular. While such a shape can create good optical cavity, the strain distribution was unsatisfactory because of the strain being strongly formed at the corner of the intersection region. To prevent or minimise disturbing the strain distribution, both 3D finite-domain time-difference (FDTD) and FEM mechanical simulations were performed by running a parameter sweep to find an optimised curvature of the intersection region to achieve uniform strain distribution while maintaining a satisfactory optical cavity.

For optimisation of the DBR (mirror) design, the air trench width and period may be calculated by considering the target wavelength. For example, for an optical device employing air trenches for DBRs and a Ge layer, the relationship [((air trench width×1 (i.e., refractive index of air))+((period−air trench width)×4.1 (i.e., refractive index of Ge)))×2] may be used to determine the corresponding target wavelength (e.g., 1,920 nm). The relationship indicates that the effective length of one period of DBR having an air trench and one Ge slab may be approximately half of the target wavelength. The effective length indicates the physical length multiplied by the refractive index of materials. If the air trench width becomes thinner or smaller, scattering at the mirror becomes lower but the light may be transmitted through the mirror more easily. If the air trench becomes thicker or larger, less light is transmitted through the mirror, but scattering at the mirror becomes higher. The mirror design may be optimised by running a parameter sweep to find the air trench width that reduces scattering at the mirror.

Optimisation of the DBR (mirror) location may also be carried out. If the mirror is too close to the center or the intersection region, a strong strain is formed at the mirror edge as the mirror edge and the edge of the stressing pad come closer to each other. This makes the structure relatively easier to break at the mirror edge. To avoid or minimise this, the DBR (mirror) may be placed further away from the intersection region. However, if the mirror is placed too far from the center or the intersection region, there is a loss as the light has to travel a further distance and, therefore, the light diverges more, potentially leading to more diverged light passing through or propagating beyond the mirror edge. Therefore, the mirror is located close to the intersection region in a range that does not or may not cause strong strain at the edge of the mirror.

Optical characterisation has been carried out. To investigate the effect of strain, pump power and temperature on the optical gain in the biaxially strained Ge crossbeam structures, comprehensive photoluminescence (PL) measurements and analyses have been performed. A 1,550-nm-pulsed laser with pulse width and repetition rate of 50 ns and 3 MHz, respectively, was employed. The sample was mounted in a cryostat operating at a wide temperature range between about 4 K and about 300 K. The pump laser was focused onto the sample using a 15× objective lens producing a spot size of around 10 μm, and the signal was collected by the same objective lens and subsequently coupled into a grating which diffracted the spectrum onto a 1D-array extended InGaAs (indium gallium arsenide) detector with a detection range between about 1.4 μm and about 2.1 μm.

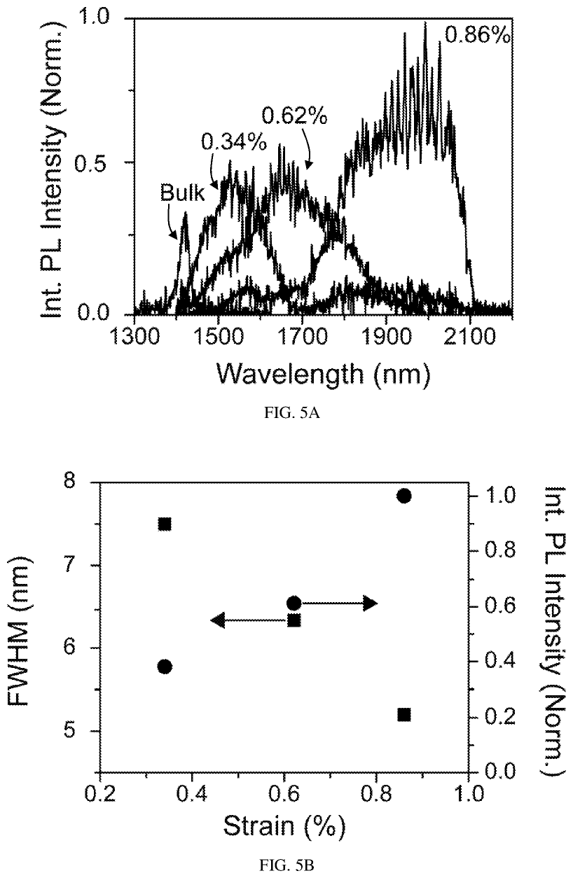

FIG. 5A shows the PL spectra from crossbeam structures with different strains on a single chip, illustrating the results for applied biaxial strains of about 0.34%, about 0.62%, and about 0.86%. The measurement temperature was kept at 4 K. The different strains were achieved by using differently sized stressing pads. For comparison, the PL spectrum from an unstrained Ge bulk area is also provided in FIG. 5A, which shows an emission peak at ˜1,420 nm. This peak position is consistent with the calculated emission peak at a cryogenic temperature according to a known empirical model.

By increasing the biaxial tensile strain from about 0.34% to about 0.86%, the PL intensity is clearly increased while the peak wavelength position is shifted by ˜500 nm. Tensile strain is expected to reduce the energy difference between the direct Γ valley and the indirect L valleys, thus increasing the electron population in the direct Γ valley that contributes to the radiative recombination. The energy gap for the direct radiative optical transition is also reduced at higher tensile strain, which is the main reason for such a large peak wavelength shift. The integrated intensity may be calculated from the area underneath the whole curve. The full width at half maximum (FWHM) may be extracted by utilizing Lorentzian fitting functions. The FWHM of the broad spontaneous emission is also significantly increased at higher strain, and this may be attributed to the strain-induced valence band splitting and strain non-homogeneity. The quantitative analysis of the integrated PL intensity as a function of strain shows a three-fold increase of the PL intensity as strain is increased from 0.34% to 0.86%, as may be observed from FIG. 5B. Tensile strain may also be expected to increase the optical gain because of the increased electron population fraction in the direct Γ valley with respect to the indirect L valleys. The increased optical gain (i.e., reduced optical loss) may also be clearly evidenced by the reduced FWHM of the cavity mode at higher strain as shown in FIG. 5B.

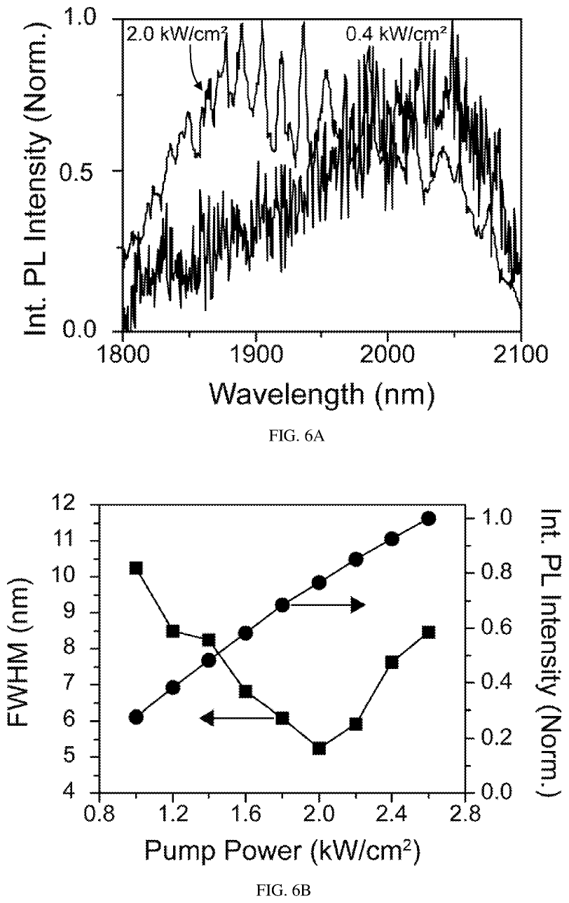

FIG. 6A shows results of the power-dependent PL spectra of a 0.86%-strained Ge crossbeam structure. The measurement temperature was kept at 4 K. At a low pump power of about 0.4 kW/cm², the PL spectrum shows a broad spontaneous emission without any clear, sharp cavity peaks. The peak position of the broad spontaneous emission is at the cut-off of the InGaAs detector (2,100 nm) used. At an increased pump power of about 2.0 kW/cm², sharp cavity modes are clearly observed as the optical loss is compensated by the material gain. It may be observed that the peak position of the broad emission is also shifted to a shorter wavelength at ˜1,900 nm, and this may be ascribed to the band filling effect. At higher pump power, the excited holes start filling up the second valence band while at low pump power, the pumped holes only occupy the highest valence band.

FIG. 6B shows the linewidth of the cavity mode at ˜1,940 nm and the integrated PL intensity as a function of pump power. The FWHM value of the investigated cavity mode is reduced to ˜5.2 nm at a pump power of about 2.0 kW/cm², manifesting the reduced loss at an increased pump power. However, the cavity mode starts broadening as the pump power is further increased. This is in contrast to reported lasing results in known uniaxially and biaxially strained Ge structures.

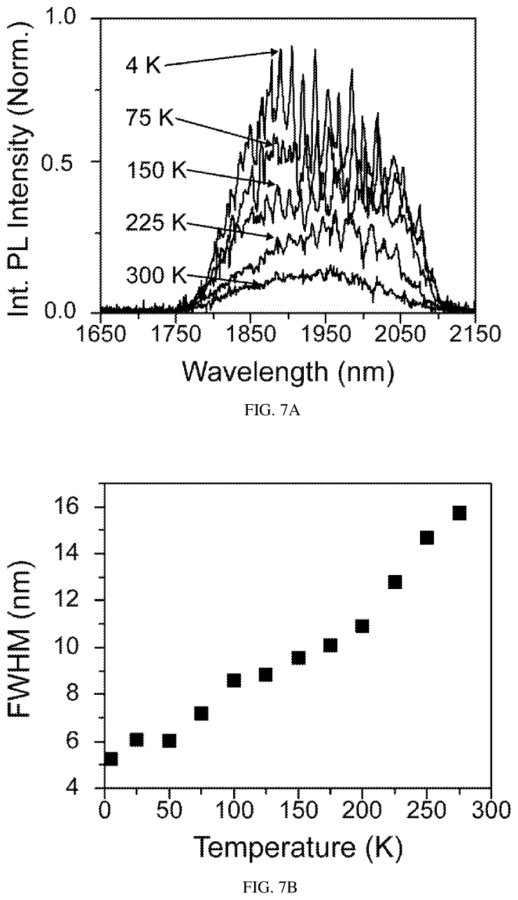

Temperature-dependent PL measurements were performed at temperatures between about 4 K and about 300 K for a 0.86%-strained structure, and the results are shown in FIG. 7A. At 300 K, the PL spectrum only shows a broad spontaneous emission without any cavity modes owing to a large material loss at elevated temperature. As the temperature is decreased, the cavity modes become sharper and bigger in intensity as shown in FIGS. 7A and 7B. The FWHM of the cavity mode at ˜1,940 nm is significantly reduced from about 15.8 nm to about 5.2 nm as the temperature is reduced from about 275 K to about 4 K, suggesting substantially improved optical gain at lower temperatures. The factors for this optical gain enhancement at a low temperature may include reduced inter-valence band absorption (IVBA) and increased strain at a low temperature. The increase of the induced biaxial strain at a low temperature is possible in the structural geometry in various embodiments, where the patterned Ge crossbeam structure is suspended in air by removing the underlying sacrificial layer(s) through etched holes or regions. The weakly distributed residual strain in the Ge layer may arise from the thermal expansion coefficient mismatch between Si and Ge, and this residual strain may be concentrated around the central area (see, for example, intersection region 210, FIG. 4B) of the crossbeam structure, thus allowing the accumulation of a large biaxial strain. Since the strength of the (residual) strain is temperature-dependent and becomes higher at a low(er) temperature, the decrease of the operating temperature increases the (residual) strain, which in turn may further increase the localised biaxial strain in the central area of the crossbeam structure. This combined effect of temperature and strain may have an impact on the optical gain, which is evidenced by the three-fold reduction of the FWHM value of a cavity resonance at ˜1,940 nm when the temperature is reduced from about 275 K to about 4 K.

The achieved biaxial strain of about 0.86% is comparatively lower to reported values of known approaches because of the presence of optical cavity in the optical devices of various embodiments. The geometrical strain amplification technique may cause undesired or unwanted strained regions at the corner of neck regions and the reflectors/mirrors, potentially causing a fracture of the structure easily and leading to lower strain. Thus, cavity integration into the biaxial strain structure requires very careful optimisation of the intersection region or central area design, mirror design, and location, and such optimisation is as described herein.

The optical devices of various embodiments may be employed as an optical (light) source, e.g., a laser. When the intersection region (e.g., 210) is optically pumped by an external pumping laser (pump signal), the absorbed energy is converted to the emission of light. This is referred to as spontaneous emission. With spontaneous emission from the intersection region, the optical device can function as a light source. The light can be confined by the DBR mirrors (e.g., 212a, 212b). When the confined light overlaps with the gain medium at the intersection region, the light can be amplified. This is referred to as stimulated emission. When the amplification overcomes the loss caused while the confined light travels between two DBR mirrors, the confined light will keep on being amplified as it travels. This is referred to as lasing. Thus, the pump signal is external pumping laser, and the output light is spontaneous emission and/or its amplified light. The direction of the output light is parallel to the Ge layer (e.g., 204). The function of the crossbeam structure (e.g., 206) in the lasing process is to induce/enhance the biaxial tensile strain in the central area (intersection region) by four side stressing pads or elements (e.g., 228a, 228b) so that a gain medium for lasing may be achieved. The function of the DBR mirrors is to confine the light within the crossbeam structure. Light is confined between each pair of two DBR mirrors. The DBRs may be designed to make a path by having the air trenches removed at the center of the DBR mirrors to allow the confined light to propagate to other places.

As a non-limiting example, the wavelength of the output light may be near ˜1,940 nm. The wavelength may be dependent on the amount of biaxial strain. The wavelength becomes longer as the biaxial strain increases.

The optical device of various embodiments can function as a laser where sufficient optical gain is obtained. This may be achieved by achieving direct bandgap Ge with more than 1.7% biaxial strain. To achieve such a high biaxial strain, the intersection region would need to withstand such large strain without fracture. In order to avoid fracture, the defect density may be reduced by improving material quality through various methods such as, for example, thermal annealing. Given the improved material quality, the strain level may be increased beyond 1.7% by increasing the size of the stressing pads.

As described above, the techniques disclosed herein may provide a monolithic crossbeam structure embedded with DBR mirrors that may simultaneously achieve large biaxial strains and high-quality factors. The geometrical amplification technique employed in the disclosed techniques may allow the creation of multiple structures with distinct strain levels on a single chip. Structural analyses via a combination of simulations and experiments confirm a fairly uniform strain. In other words, the structures of various embodiments may enable strain uniformity. Comprehensive PL studies were performed to investigate the evolution of cavity modes under different conditions with strain, pump power, and temperature as variables. It is observed that there is a three-fold reduction of the FWHM value of the cavity mode by harnessing both lowered material losses or lowered IVBA, and increased biaxial strain at lower operating temperatures. The biaxially strained Ge crossbeam design of various embodiments may enable achieving a low-threshold on-chip laser for fiber-based optical communications. The techniques disclosed herein may open up an avenue towards creating strained Ge lasers for fiber-based optical communications.

The structures or devices obtained using the techniques disclosed herein may have various applications. The creation of a low-threshold Ge laser enabled by large, uniform biaxial strain can lead to the completion of photonic-integrated circuits that may revolutionize a wide variety of disruptive technologies including LiDAR (light detection and ranging) and 3D (three-dimensional) facial recognition sensors. The ability to integrate lasers emitting at distinct wavelengths on a single chip via geometrically tunable strain may also allow the realisation of wavelength division multiplexed optical interconnects.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. An optical device comprising:
a substrate;
a semiconductor layer on the substrate, the semiconductor layer having an initial tensile strain and comprising a monolithic crossbeam structure defined therein; and
an optical cavity optically coupled to the monolithic crossbeam structure,
wherein the monolithic crossbeam structure comprises a first beam and a second beam arranged at least substantially orthogonal to each other and intersecting each other at an intersection region, the intersection region being subjected to a tensile strain that is increased relative to the initial tensile strain.

2. (canceled)

3. The optical device as claimed in claim 1, wherein a plurality of etched regions are defined in the semiconductor layer to define the monolithic crossbeam structure, the plurality of etched regions being arranged along two orthogonal axes.

4. The optical device as claimed in claim 3, wherein, for each etched region of the plurality of etched regions, the etched region is defined by:
a first section having a curvature that tapers decreasingly in a direction towards the intersection region; and
a second section extending from the first section in a direction away from the intersection region.

5. The optical device as claimed in claim 4, wherein the first sections of adjacent etched regions of the plurality of etched regions define a neck region therebetween, wherein a minimum width of the neck region is between about 700 nm and about 2000 nm.

6. The optical device as claimed in claim 1, wherein the optical cavity is defined by a pair of distributed Bragg reflectors arranged on opposite sides of the intersection region along a longitudinal axis of the first beam.

7. The optical device as claimed in claim 6, wherein, for each distributed Bragg reflector of the pair of distributed Bragg reflectors, a plurality of air trenches are defined in the distributed Bragg reflector, wherein a number of the plurality of air trenches is between 7 and 10.

8. The optical device as claimed in claim 6, wherein a distance between each distributed Bragg reflector of the pair of distributed Bragg reflectors and the intersection region is between about 12 μm and about 20 μm.

9. The optical device as claimed in claim 6, wherein the optical cavity is further defined by an additional pair of distributed Bragg reflectors arranged on opposite sides of the intersection region along a longitudinal axis of the second beam.

10. The optical device as claimed in claim 1, wherein the monolithic crossbeam structure further comprises:
a first pair of stressing pads extended from the first beam and arranged on opposite sides of the intersection region along a longitudinal axis of the first beam; and
a second pair of stressing pads extended from the second beam and arranged on opposite sides of the intersection region along a longitudinal axis of the second beam.

11. (canceled)

12. (canceled)

13. A method of forming an optical device comprising:
forming a semiconductor layer on a substrate, the semiconductor layer that is formed having an initial tensile strain;
forming a monolithic crossbeam structure in the semiconductor layer, wherein the monolithic crossbeam structure comprises a first beam and a second beam arranged at least substantially orthogonal to each other and intersecting each other at an intersection region, the intersection region being subjected to a tensile strain that is increased relative to the initial tensile strain; and
optically coupling an optical cavity to the monolithic crossbeam structure.

14. (canceled)

15. The method as claimed in claim 13, wherein forming the monolithic crossbeam structure comprises defining a plurality of etched regions in the semiconductor layer to form the monolithic crossbeam structure, the plurality of etched regions being arranged along two orthogonal axes.

16. The method as claimed in claim 15, wherein defining the plurality of etched regions comprises defining, for each etched region of the plurality of etched regions, a first section having a curvature that tapers decreasingly in a direction towards the intersection region, and a second section extending from the first section in a direction away from the intersection region.

17. The method as claimed in claim 16, wherein the first sections of adjacent etched regions of the plurality of etched regions define a neck region therebetween, wherein a minimum width of the neck region is between about 700 nm and about 2000 nm.

18. The method as claimed in claim 13, wherein optically coupling the optical cavity to the monolithic crossbeam structure comprises forming a pair of distributed Bragg reflectors arranged on opposite sides of the intersection region along a longitudinal axis of the first beam to define the optical cavity.

19. The method as claimed in claim 18, wherein forming the pair of distributed Bragg reflectors comprises defining, for each distributed Bragg reflector of the pair of distributed Bragg reflectors, a plurality of air trenches in the distributed Bragg reflector, wherein a number of the plurality of air trenches is between 7 and 10.

20. The method as claimed in claim 18, wherein a distance between each distributed Bragg reflector of the pair of distributed Bragg reflectors and the intersection region is between about 12 μm and about 20 μm.

21. The method as claimed in claim 18, wherein optically coupling the optical cavity to the monolithic crossbeam structure further comprises forming an additional pair of distributed Bragg reflectors arranged on opposite sides of the intersection region along a longitudinal axis of the second beam to define the optical cavity.

22. The method as claimed in claim 13, wherein forming the monolithic crossbeam structure further comprises:
forming a first pair of stressing pads extended from the first beam and arranged on opposite sides of the intersection region along a longitudinal axis of the first beam; and
forming a second pair of stressing pads extended from the second beam and arranged on opposite sides of the intersection region along a longitudinal axis of the second beam.

23. (canceled)

24. (canceled)

25. A method of controlling an optical device comprising:
applying an input light to an intersection region of the optical device comprising:
a substrate;
a semiconductor layer on the substrate, the semiconductor layer having an initial tensile strain and comprising a monolithic crossbeam structure defined therein; and
an optical cavity optically coupled to the monolithic crossbeam structure,
wherein the monolithic crossbeam structure comprises a first beam and a second beam arranged at least substantially orthogonal to each other and intersecting each other at the intersection region, the intersection region being subjected to a tensile strain that is increased relative to the initial tensile strain.

26. The method as claimed in claim 25, wherein the monolithic crossbeam structure of the optical device is suspended over the substrate of the optical device, the method further comprising decreasing a temperature of the optical device.
